(19) United States
(12) Patent Application Publication
(10) Pub. No.: US 2003/0002735 A1
(43) Pub. Date: Jan. 2, 2003

(54) Image processing method and image processing apparatus

(76) Inventors: Hideaki Yamamoto, Hino (JP); Toru Kawabe, Hachioji (JP); Takao Misawa, Hachioji (JP); Masahide Hoshino, Irumashi (JP)

Correspondence Address: Cameron Kerrigan, Squire, Sanders & Dempsey L.L.P., Suite 300, One Maritime Plaza, San Francisco, CA, 94111, US

(21) Appl. No.: 10/183,732

(22) Filed: Jun. 25, 2002

(30) Foreign Application Priority Data
Jun. 29, 2001 (JP) 2001-199249
Jun. 29, 2001 (JP) 2001-199844
Jul. 2, 2001 (JP) 2001-200719

(51) Int. Cl. G06T 5/00; H04N 1/58; G06K 9/32; G06K 9/03; H04N 1/047; G03F 3/08; G01N 21/00

(52) U.S. Cl. 382/167; 382/274; 382/294; 382/275; 358/506; 358/519; 356/239.8; 356/237.3; 358/505; 358/509

(57) ABSTRACT

There is described a method of processing an image recorded on a film, by which differences of gamma values between RGB image information and information on foreign substances or damages are corrected. The method comprises the steps of: irradiating a plurality of lights, whose wavelengths are different relative to each other, onto the film; reading the image by detecting the plurality of lights transmitted through the film or reflected from the film placed, so as to generate a plurality of color image data sets corresponding to a plurality of color images included in the image; and processing the plurality of color image data sets, so as to keep each of relative relationships or each of ratios, between gamma values of the plurality of color images, substantially constant.

### BACKGROUND OF THE INVENTION

The present invention relates to an image processing method and image processing apparatus for correcting differences of gamma values between RGB image information and information on foreign substances and damages, and particularly to an image processing method and image processing apparatus for providing a uniform image despite changes in imaging magnification, and an image processing method and image processing apparatus for correcting the misregistration of visible information.

The image taken on a photographic film such as a negative film and positive film (reverse film) (hereinafter referred to as “film”) is printed on photographic paper by a printing apparatus based on digital exposure put into practical use in recent years. Namely, this is a digital printing system which, subsequent to photoelectric reading of the film image and conversion of the read image into a digital signal, provides various steps of image processing, and scans and exposes photographic paper by recording light modulated in conformity to the aforementioned image data as image data to be recorded, whereby the aforementioned image is recorded.

Such a digital printer system uses a scanner for photoelectric reading of the image recorded on a film. However, if the film containing foreign substances such as dust or dirt and damages are picked up by infrared rays of a scanner, foreign substances and damages alone will be picked up as images.

In a disclosure (U.S. Pat. No. 2,559,970), this property is used to correct foreign substances and damages on the image, based on the image of foreign substances and damages picked up by infrared rays. Incidentally, correction of foreign substances and damages is carried out according to the density value contained in information on foreign substances and damages, and this raises a problem of correction accuracy being deteriorated if there is any difference of gamma values between visible information and information on foreign substances and damages.

Further, changes in imaging magnification of the scanner may cause changes in the amount of pixels among different pieces of color information of an image, MTF correlation, a focal point for each color, ratio of gamma value, shading pattern and others. If there is a change in the magnification of imaging by a scanner, a difference in image quality may result.

Since a difference in image may result if there is a change in the magnification of imaging by a scanner, a change of the relationship will occur between visible information and information on foreign substances and damages, with the result that foreign substance and damage connection performance is changed by magnification.

In the aforementioned digital printer system, the image recorded on the film by a scanner is photoelectrically read out, but misregistration of optical axis caused by imaging element installation accuracy, document feed misalignment, lens aberration and lens installation accuracy cannot be completely eliminated in the step of manufacturing a scanner. As a result, these factors are linked together in a complicated manner to cause misregistration of the pixels, with the result that sharp images are deteriorated and colors are blurred on the contours of the picked up image.

As a result of improved quality of digital images in recent years on the other hand, the problem of poor image quality due to color misregistration is getting more serious than before. The amount of color misregistration is changed among pieces of visible information consisting of color information perceptible to humans as a photograph or image, e.g. among blue, green and red, because of the changes of each characteristic function due to fluctuations of an equipment status or changes of characteristic functions due to changes of magnification in an image pickup apparatus loaded with a zoom lens. Further, if an image is picked up from the film containing foreign substances including dust or dirt and damages in the scanner, only foreign substances or damages are picked up.

Incidentally, partial correction failure will occur if there is a misregistration between the visible information consisting of color information perceptible to humans as a photograph or image and the information on foreign substances including dust or dirt and damages that were not present originally, because of the misregistration in coordinate positions between visible ray and information on foreign substances and damages, difference in sharpness between the visible ray and infrared ray, changes in each characteristic function due to the fluctuation of an equipment status, or changes in each characteristic function resulting from the fluctuation of magnification in the image pickup apparatus loaded with a zoom lens. If blurring occurs, the portions other than damages will be corrected.

### SUMMARY OF INVENTION

To overcome the abovementioned drawbacks in conventional image-processing apparatus, it is the first object of the present invention to provide an image processing method and image processing apparatus capable of improving the image quality and the accuracy of correcting the errors attributable to the foreign substances and damages by maintaining the correlation or ratio of the gamma value constant between different pieces of color information.

The second object of the present invention is to provide an image processing method and image processing apparatus capable of ensuring stable image quality despite changes in the imaging magnification and improving the performance of correcting the error attributable to foreign substances and damages, independently of imaging magnification.

The third object of the present invention is to provide an image processing method and image processing apparatus which correct other visible information with reference to G of the visible information, thereby preventing deterioration of G containing much of the information on brightness as the major component of sharpness and avoiding deterioration of image quality due to color misregistration of the aforementioned visible information; and, at the same time, correct information on foreign substances and damages with reference to visible information, thereby avoiding deterioration of image quality in correction of the foreign substances and damages.

Accordingly, to overcome the cited shortcomings, the abovementioned objects of the present invention can be attained by image-processing methods and apparatus described as follow.

(1) A method of processing an image recorded on a film, comprising the steps of: irradiating a plurality of lights, whose wavelengths are different relative to each other, onto the film; reading the image by detecting the plurality of lights transmitted through the film or reflected from the film placed, so as to generate a plurality of color image data sets corresponding to a plurality of color images included in the image; and processing the plurality of color image data sets, so as to keep each of relative relationships or each of ratios, between gamma values of the plurality of color images, substantially constant.

(2) The method of item 1, wherein the plurality of color images include a Red image, a Green image and a Blue image.

(3) The method of item 1, wherein the plurality of color images include a Red image, a Green image, a Blue image and a specific image having a wavelength other than those of the Red image, the Green image and the Blue image.

(4) The method of item 3, wherein the specific image is an infrared image.

(5) The method of item 3, wherein the Green image is selected as a reference image for processing the plurality of color image data sets, and each of the relative relationships or each of the ratios, between a gamma value of the Green image and each of gamma values of the Red image, the Blue image and the specific image, is kept substantially constant.

(6) The method of item 5, wherein each of the relative relationships or each of the ratios, between a gamma value of the Green image and each of gamma values of the Red image and the Blue image, is kept substantially constant.

(7) The method of item 1, wherein each of the gamma values is measured by reading a plurality of solid image areas, whose densities are different relative to each other, and each of which is recorded on each of a plurality of films.

(8) The method of item 1, wherein each of the gamma values is measured by reading a plurality of solid image areas, whose densities are different relative to each other, and which are recorded within a single frame of a film; and wherein the plurality of solid image areas are arrayed in order of their density strengths.

(9) The method of item 8, wherein each density difference value between two adjacent solid image areas of the plurality of solid image areas is not greater than 0.5.

(10) The method of item 1, wherein each of the gamma values of the plurality of color images is compensated for, so as to keep each of the relative relationships or each of the ratios constant; and wherein each of compensated gamma values of the plurality of color images is changed corresponding to a kind of the film.

(11) An apparatus for processing an image recorded on a film, comprising: a light source to emit a plurality of lights, whose wavelengths are different relative to each other, and which are irradiated onto the film; an image-reading section to read the image by detecting the plurality of lights transmitted through the film or reflected from the film placed, so as to generate a plurality of color image data sets corresponding to a plurality of color images included in the image; and an image-processing section to process the plurality of color image data sets, so as to keep each of relationships or each of ratios, between gamma values of the plurality of color images, substantially constant.

(12) The apparatus of item 11, wherein the plurality of color images include a Red image, a Green image and a Blue image.

(13) The apparatus of item 11, wherein the plurality of color images include a Red image, a Green image, a Blue image and a specific image having a wavelength other than those of the Red image, the Green image and the Blue image.

(14) The apparatus of item 13, wherein the specific image is an infrared image.

(15) The apparatus of item 13, wherein the Green image is selected as a reference image for processing the plurality of color image data sets, and each of the relative relationships or each of the ratios, between a gamma value of the Green image and each of gamma values of the Red image, the Blue image and the specific image, is kept substantially constant.

(16) The apparatus of item 15, wherein each of the relative relationships or each of the ratios, between a gamma value of the Green image and each of gamma values of the Red image and the Blue image, is kept substantially constant.

(17) The apparatus of item 11, wherein each of the gamma values is measured by reading a plurality of solid image areas, whose densities are different relative to each other, and each of which is recorded on each of a plurality of films.

(18) The apparatus of item 11, wherein each of the gamma values is measured by reading a plurality of solid image areas, whose densities are different relative to each other, and which are recorded within a single frame of a film; and wherein the plurality of solid image areas are arrayed in order of their density strengths.

(19) The apparatus of item 18, wherein each density difference value between two adjacent solid image areas of the plurality of solid image areas is not greater than 0.5.

(20) The apparatus of item 11, wherein each of the gamma values of the plurality of color images is compensated for, so as to keep each of the relative relationships or each of the ratios constant; and wherein each of compensated gamma values of the plurality of color images is changed corresponding to a kind of the film.

(21) A method of processing an image recorded on a document, comprising the steps of: irradiating a plurality of lights, whose wavelengths are different relative to each other, onto the document; reading the image by detecting the plurality of lights transmitted through the document or reflected from the document placed, so as to generate a plurality of color image data sets corresponding to a plurality of color images included in the image; and processing the plurality of color image data sets, so as to compensate for photographing-response characteristics in respect to each of the plurality of color images, corresponding to variations of an image-magnification factor for every photographing-operation.

(22) The method of item 21, wherein an image of a foreign substance or a scar on the document is substantially eliminated by compensating for the photographing-response characteristics.

(23) The method of item 21, wherein either an amount-of-change or a rate-of-change, between first photographing-response characteristics at a certain image-magnification factor, serving as a reference image-magnification factor, and second photographing-response characteristics at another image-magnification factor, is compensated for.

(24) The method of item 21, wherein the photographing-response characteristics includes at least one of factors, which are misregistration of the plurality of color images, correlation of MTF characteristics, focusing properties of the plurality of color images, ratios between gamma values of the plurality of color images, noises and shading patterns.

(25) The method of item 21, wherein the photographing-response characteristics are compensated for within a predetermined range, irrespective of any variations of the image-magnification factor.

(26) The method of item 23, wherein a best image-quality is obtained at the reference image-magnification factor without compensating for the photographing-response characteristics in a range of the variations of the image-magnification factor.

(27) The method of item 23, wherein an average image-quality is obtained at the reference image-magnification factor without compensating for the photographing-response characteristics in a range of the variations of the image-magnification factor.

(28) The method of item 21, wherein a table of compensation values is provided for every image-magnification factor to be set.

(29) The method of item 21, wherein a table of compensation values is provided for each of image-magnification factors divided into predetermined intervals, and gaps between the image-magnification factors are linearly interpolated.

(30) The method of item 21, wherein a table of compensation values is provided for each of predetermined ranges of the image-magnification factor, and the photographing-response characteristics are compensated for by employing a same compensation value within each of the predetermined ranges of the image-magnification factor.

(31) The method of item 23, wherein first compensation values at the reference image-magnification factor are stored, and second compensation values at another image-magnification factor other than the reference image-magnification factor are differential components of the first compensation values.

(32) The method of item 31, wherein variations of compensation values by the image-magnification factor are calculated by employing a formula.

(33) The method of item 21, wherein the document is a photographic-film.

(34) An apparatus for processing an image recorded on a document, comprising: a light source to emit a plurality of lights, whose wavelengths are different relative to each other, and which are irradiated onto the document; an imagereading section to read the image by detecting the plurality of lights transmitted through the document or reflected from the document placed, so as to generate a plurality of color image data sets corresponding to a plurality of color images included in the image; and an image-processing section to process the plurality of color image data sets, so as to compensate for photographing-response characteristics in respect to each of the plurality of color images, corresponding to variations of an image-magnification factor for every photographing-operation.

(35) The apparatus of item 34, wherein an image of a foreign substance or a scar on the document is substantially eliminated by compensating for the photographing-response characteristics.

(36) The apparatus of item 34, wherein either an amount-of-change or a rate-of-change, between first photographing-response characteristics at a certain image-magnification factor, serving as a reference image-magnification factor, and second photographing-response characteristics at another image-magnification factor, is compensated for.

(37) The apparatus of item 34, wherein the photographing-response characteristics includes at least one of factors, which are misregistration of the plurality of color images, correlation of MTF characteristics, focusing properties of the plurality of color images, ratios between gamma values of the plurality of color images, noises and shading patterns.

(38) The apparatus of item 34, wherein the photographing-response characteristics are compensated for within a predetermined range, irrespective of any variations of the image-magnification factor.

(39) The apparatus of item 36, wherein a best image-quality is obtained at the reference image-magnification factor without compensating for the photographing-response characteristics in a range of the variations of the image-magnification factor.

(40) The apparatus of item 36, wherein an average image-quality is obtained at the reference image-magnification factor without compensating for the photographing-response characteristics in a range of the variations of the image-magnification factor.

(41) The apparatus of item 34, wherein a table of compensation values is provided for every image-magnification factor to be set.

(42) The apparatus of item 34, wherein a table of compensation values is provided for each of image-magnification factors divided into predetermined intervals, and gaps between the image-magnification factors are linearly interpolated.

(43) The apparatus of item 34, wherein a table of compensation values is provided for each of predetermined ranges of the image-magnification factor, and the photographing-response characteristics are compensated for by employing a same compensation value within each of the predetermined ranges of the image-magnification factor

(44) The apparatus of item 36, wherein first compensation values at the reference image-magnification factor are stored, and second compensation values at another image-magnification factor other than the reference image-magnification factor are differential components of the first compensation values.

(45) The apparatus of item 44, wherein variations of compensation values by the image-magnification factor are calculated by employing a formula.

(46) The apparatus of item 34, wherein the document is a photographic-film.

(47) A method of processing an image recorded on a film, comprising the steps of: irradiating a plurality of lights, whose wavelengths are different relative to each other, onto the film; reading the image by detecting the plurality of lights transmitted through the film or reflected from the film placed, so as to generate a plurality of color image data sets corresponding to a plurality of color images included in the image; and processing the plurality of color image data sets, so as to compensate for misregistrations between positional coordinates of the plurality of color images.

(48) The method of item 47, wherein each of the plurality of color images is constituted by pixels, which are arrayed in two-dimensional directions of rows and lines, and are divided into a predetermined number of unit pixel areas; and wherein the misregistrations between the positional coordinates of the plurality of color images are compensated for by deforming pixels included in each of the unit pixel areas with each of deforming amounts being different relative to each other.

(49) The method of item 47, wherein the plurality of color images include a Red image, a Green image and a Blue image; and wherein the misregistrations between the positional coordinates of the plurality of color images are compensated for by matching positional coordinates of the Red image and the Blue image with that of the Green image.

(50) The method of item 49, wherein a light, having a wavelength other than those of the Red image, the Green image and the Blue image is irradiated onto the film to capture a specific image of a foreign substance or a scar on the film; and wherein, after matching a positional coordinate of the specific image with those of the Red image, the Green image and the Blue image, foreign substance or scar images, recorded on the Red image, the Green image and the Blue image, are compensated for, based on information in regard to the specific image of the foreign substance or the scar.

(51) The method of item 50, wherein the positional coordinate of the specific image is matched with a positional coordinate of the Green image.

(52) The method of item 50, wherein an Infrared light is irradiated onto the film to capture the specific image of the foreign substance or the scar on the film; and

(53) The method of item 47, wherein a chart, on which either vertical lines or horizontal lines, or both of them are depicted, is employed for detecting misregistrations between the positional coordinates of the plurality of color images.

(54) The method of item 53, wherein either the vertical lines or the horizontal lines, or both of them are arrayed in (a) vertical and/or horizontal direction(s) with predetermined intervals between them in the chart.

(55) The method of item 54, wherein the chart has only a single color-sensitive component.

(56) The method of item 53, wherein the chart is made of such a material that an Infrared-transmittance varies with changes in density.

(57) The method of item 53, wherein the chart is made of one of materials including a metal-plate made by etching, a vaporized glass filter and a monochrome film.

(58) The method of item 47, wherein compensation amounts for compensating the positional coordinates of the plurality of color images are changed, corresponding to every kind of the film.

(59) The method of item 58, wherein foreign substance or scar images are compensated for, after compensating the positional coordinates of the plurality of color images.

(60) The method of item 58, wherein foreign substance or scar images are compensated for, referring to the compensation amounts for compensating the positional coordinates of the plurality of color images.

(61) The method of item 58, wherein, based on individual compensation amounts detected in advance, compensation amounts newly acquired or compensation calculations, the compensation amounts are changed, corresponding to everyone of image-magnification factors.

(62) An apparatus for processing an image recorded on a film, comprising: a light source to emit a plurality of lights, whose wavelengths are different relative to each other, and which are irradiated onto the film; an image-reading section to read the image by detecting the plurality of lights transmitted through the film or reflected from the film placed, so as to generate a plurality of color image data sets corresponding to a plurality of color images included in the image; and an image-processing section to process the plurality of color image data sets, so as to compensate for misregistrations between positional coordinates of the plurality of color images.

(63) The apparatus of item 62, wherein each of the plurality of color images is constituted by pixels, which are arrayed in two-dimensional directions of rows and lines, and are divided into a predetermined number of unit pixel areas; and wherein the misregistrations between the positional coordinates of the plurality of color images are compensated for by deforming pixels included in each of the unit pixel areas with each of deforming amounts being different relative to each other.

(64) The apparatus of item 62, wherein the plurality of color images include a Red image, a Green image and a Blue image; and wherein the misregistrations between the positional coordinates of the plurality of color images are compensated for by matching positional coordinates of the Red image and the Blue image with that of the Green image.

(65) The apparatus of item 64, wherein a light, having a wavelength other than those of the Red image, the Green image and the Blue image is irradiated onto the film to capture a specific image of a foreign substance or a scar on the film; and wherein, after matching a positional coordinate of the specific image with those of the Red image, the Green image and the Blue image, foreign substance or scar images, recorded on the Red image, the Green image and the Blue image, are compensated for, based on information in regard to the specific image of the foreign substance or the scar.

(66) The apparatus of item 65, wherein the positional coordinate of the specific image is matched with a positional coordinate of the Green image.

(67) The apparatus of item 65, wherein an Infrared light is irradiated onto the film to capture the specific image of the foreign substance or the scar on the film; and

(68) The apparatus of item 62, wherein a chart, on which either vertical lines or horizontal lines, or both of them are depicted, is employed for detecting misregistrations between the positional coordinates of the plurality of color images.

(69) The apparatus of item 68, wherein either the vertical lines or the horizontal lines, or both of them are arrayed in (a) vertical and/or horizontal direction(s) with predetermined intervals between them in the chart.

(70) The apparatus of item 69, wherein the chart has only a single color-sensitive component.

(71) The apparatus of item 68, wherein the chart is made of such a material that an Infrared-transmittance varies with changes in density.

(72) The apparatus of item 68, wherein the chart is made of one of materials including a metal-plate made by etching, a vaporized glass filter and a monochrome film.

(73) The apparatus of item 62, wherein compensation amounts for compensating the positional coordinates of the plurality of color images are changed, corresponding to every kind of the film.

(74) The apparatus of item 73, wherein foreign substance or scar images are compensated for, after compensating the positional coordinates of the plurality of color images.

(75) The apparatus of item 73, wherein foreign substance or scar images are compensated for, referring to the compensation amounts for compensating the positional coordinates of the plurality of color images.

(76) The apparatus of item 73, wherein, based on individual compensation amounts detected in advance, compensation amounts newly acquired or compensation calculations, the compensation amounts are changed, corresponding to everyone of image-magnification factors.

Further, to overcome the abovementioned problems, other image-processing methods and apparatus, embodied in the present invention, will be described as follow:

The image processing method according to the present invention is characterized in that an image is read out from a film by the transmitted or reflected light of different wavelengths, a group of pixels is formed by the transmitted or reflected light and is arranged in the two-dimensional plane, and the correlation or ratio of the gamma value between different pieces of color information on multiple color images is maintained constant with respect to these multiple colors of one image.

Further, the image processing apparatus comprises; image input means for reading an image from a film by the transmitted or reflected light of different wavelengths, and image processing means for ensuring that the correlation or ratio of the gamma value between different pieces of color information on the aforementioned multiple color images is maintained constant with respect to multiple colors of one image, wherein the aforementioned group of pixels is formed by the transmitted or reflected light and is arranged in the two-dimensional plane.

According to the present invention, color information is defined as RGB information. Further, color information is an RGB and wavelength component different from the aforementioned RGB. Furthermore, color information includes RGB and Ir information.

Further, according to the present invention, when the correlation and ratio of gamma values is made constant, component G is assumed as a reference, and correlation or ratio of gamma value relative to G is made constant. The correlation or ratio of gamma value is made to agree with at least invisible information.

Gamma is measured by reading multiple films of different densities, and the correlation or ratio of gamma values between different pieces of color information is made constant. In multiple films having different densities, one frame contains multiple areas of density, and the difference of adjacent densities is reduced. For the difference of densities, the density value is 0.5 or less. The amount of gamma correction is changed for each type of film.

As described above, the correlation or ratio of gamma values between different pieces of color information is made constant, thereby improving image quality and accuracy of correcting the error resulting from foreign substances and damages.

The image processing method according to the present invention is characterized in that the an image is read from a document by means of the transmitted or reflected light of different wavelengths, a group of pixels is formed by the transmitted or reflected light and is arranged in the two-dimensional plane, and the response characteristics for imaging are corrected in response to magnification of imaging, with respect to multiple colors of one image.

The image processing apparatus according to the present invention is further characterized by comprising; image input means for reading an image from a film by the transmitted or reflected light of different wavelengths, and image processing means for correcting the response characteristics of an image in conformity to the magnification of imaging with respect to multiple colors of one image, wherein the aforementioned group of pixel is formed by the transmitted or reflected light and is arranged in the two-dimensional plane.

According to the present invention, the image quality subsequent to correction of foreign substances and damages is stabilized by correction of the changes in response characteristics.

A response characteristic of an image refers to at least one of the coordinate misregistration among various pieces of image color information, correlation of MTF, focal points of various colors, a ratio of gamma values, noise and a shading pattern.

In any magnification of imaging, the aforementioned response characteristics are corrected to stay within a predetermined range with reference to the standard state. The magnification of imaging as a reference is defined as a magnification where the image quality is the optimum without any correction being made within the range of the magnification of imaging. It can also be defined as a magnification where the image quality reaches an average level without any correction being made within the range of the magnification of imaging.

A correction value table is provided for each of the magnifications of imaging which can be set. A correction table is also provided for each of magnifications of imaging at predetermined intervals. Linear interpolation is made among these magnifications of imaging at predetermined intervals.

A correction table is provided for each of the predetermined ranges of magnification of imaging, and the same correction value is used for correction at the predetermined magnification of imaging. A correction value at a reference magnification of imaging is stored, and the correction values at magnifications other than the aforementioned magnification of imaging are the differences of correction values at the aforementioned reference magnification of imaging. The changes in correction value in conformity to the magnification of imaging can be calculated from a formula. Further, the aforementioned document is defined as a photographic film.

The image processing method according to the present invention is characterized in that an image is read out by imaging the film through the transmitted or reflected light of different wavelengths; a group of pixels is formed by the transmitted or reflected light of different wavelengths for this image reading and arranged in the two-dimensional plane; and the misregistration of coordinate position for each color component is corrected with respect to multiple colors of one image.

The image processing apparatus comprises; image input means for reading image from a film by imaging the film through the transmitted or reflected light of different wavelengths, and correction means for correcting the misregistration of coordinate position for each color component with respect to multiple colors of one image; wherein a group of pixels is formed by the transmitted or reflected light of different wavelengths input in the step of image reading and is arranged in a two-dimensional plane.

In the present invention, a group of pixels arranged in a two-dimensional plane is divided by a predetermined value and is deformed in different amount for each of the divided areas, whereby the misregistration of coordinate position of each color component is corrected. The color components consist of B, G and R. The coordinate positions of R and B are made to agree with that of G to correct misregistration of the coordinate position of each color component.

According to the present invention, information on foreign substances and damages is picked up in the range of wavelengths different from those of the B, G and R images, and the coordinates of the information on foreign substances and damages are made to agree with those of the BGR images, based on the information on foreign substances and damages, and thereafter, the foreign substances and damages of the BGR image information is corrected. Information on foreign substances and damages is picked up by infrared ray.

In the present invention, the misregistration of coordinate position is detected by a chart containing vertical and/or horizontal bars. A fixed spacing between the vertical bars and/or horizontal bars in the chart ensures simple and easy detection of the misregistration between visible information and information on foreign substances and damages.

The chart to be used is the one without multiple color sensitive components, and is made of the material where infrared transmittance changes according to the density. It can be formed of a metal plate by etching, evaporated glass film or monochrome film.

In the present invention, the correction quantity of the coordinate is switched for each type of film, and correction of foreign substances and damages is performed subsequent to correction of coordinates. Alternatively, the correction quantity is switched for each of different magnifications of imaging, according to the pre-detected individual correction quantity, newly acquired correction quantity or calculated correction quantity.

As described above, the present invention permits the misregistration of the coordinate position of each color component to be corrected, and allows the misregistration of visible information to be eliminated. The correction of the misregistration of visible information prevents the deterioration of sharpness and blurring of colors. The present invention further eliminates the difference between the information on foreign substances and damages, and visible information, thereby improving the accuracy of correcting errors related to foreign substances and damages.

### BRIEF DESCRIPTION OF THE DRAWINGS

Other objects and advantages of the present invention will become apparent upon reading the following detailed description and upon reference to the drawings in which:

FIG. 1 is a schematic configuration diagram of a scanner system;

FIG. 2 is a schematic configuration diagram of a scanner;

FIG. 3 is a diagram representing a reference imaging procedure;

FIG. 4 is a diagram representing another imaging procedure;

FIG. 5 is a diagram representing a reference step tablet;

FIG. 6 is a diagram representing a cutout display of the portion of the same color on the step table;

FIG. 7 is a diagram showing gamma values;

FIG. 8 is a diagram showing correction of gamma values;

FIG. 9 is a diagram showing correction for filling in the area of insufficiency in the Lookup Table (LUT);

FIG. 10 is a diagram representing a normal imaging procedure;

FIG. 11(a) and FIG. 11(b) are diagrams representing a chart;

FIG. 12 is a diagram representing the pixel values plotted in the arrow-marked direction using a grid chart;

FIG. 13(a) and FIG. 13(b) are diagrams showing the amount of misregistration from the chart that is represented in terms of the observation point;

FIG. 14(a) and FIG. 14(b) are diagrams showing a vertical bar chart and a horizontal bar chart, respectively;

FIG. 15(a), FIG. 15(b), FIG. 15(c) and FIG. 15(d) are diagrams showing examples of dividing an image correction area;

FIG. 16 is a diagram showing a chart;

FIG. 17 is a diagram for measuring the amplitude of the chart as a degree of sharpness;

FIG. 18(a), FIG. 18(b) and FIG. 18(c) are diagrams showing how to calculate a filter coefficient from the deterioration of amplitude;

FIG. 19 is a diagram showing a pixel misregistration quantity setup procedure; and

FIG. 20 is a diagram representing a normal imaging procedure.

### DETAILED DESCRIPTION OF THE PREFERRED EMBODIMENT

The following describes the first, second and third embodiments of the image processing method and image processing apparatus with reference to diagrams. However, it is to be understood that the present invention is not limited only to the following embodiments:

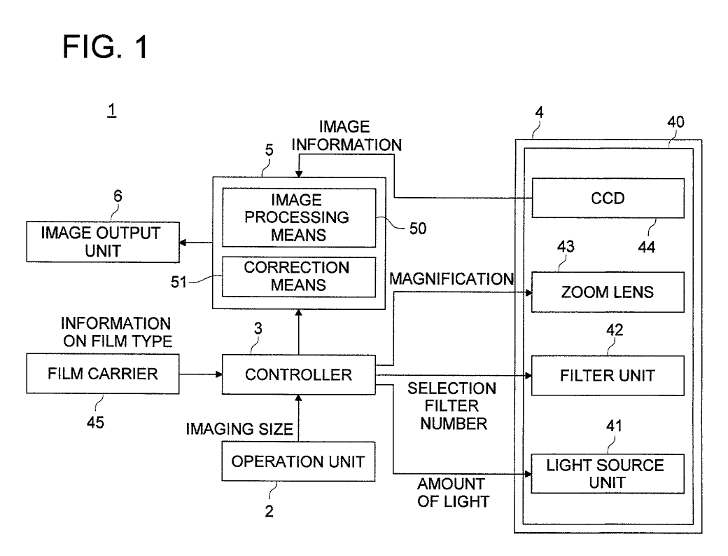

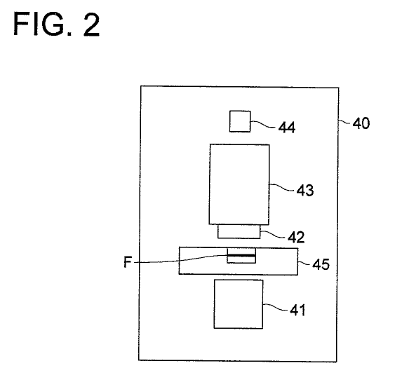

FIG. 1 is a schematic view of a scanner system common to all embodiments, and FIG. 2 is a schematic view of a scanner.

The scanner system 1 to which the present invention is applied comprises an operation unit 2, a controller 3, an image input unit 4, an image processing unit 5 and an image output unit 6. An imaging size is specified in the operation unit 2 and this imaging size specifying information is input into the controller.

The image input unit 4 as image input means is formed of a scanner 40, and comprises a light source unit 41, a filter unit 42, a zoon lens 43, a CCD 44 and a film carrier 45.

A film carrier 45 is loaded with such a film as a negative film and positive film (reversal film), and information on film type is stored in a controller 3.

Based on film size designation information and film type information, the controller 3 sets the amount of light on a light source 41 of a scanner 40, specifies a selection filter number of filter unit 42, and specifies the magnification for a zoon lens 43.

The scanner 40 photoelectrically reads the image of a film loaded into the film carrier 45 through the light of the light source 41, using a CCD 44 as an imaging element via the filter lens 42 and zoom lens 43. The image information read by this CCD 44 is converted into the digital signal and is sent to an image processing unit 5. The image processing means 50 of this image processing unit 5 provides various steps of image processing based on the correction command from the controller 3, and forms an image data to be recorded. The image information is then sent to an image output unit 6. The image output unit 6 records the image by scanning and exposing photographic paper by means of recording light modulated in conformity to image data.

The following describes the first embodiment of the present invention. Firstly, the connection of this scanner system according to the first embodiment will be described. The scanner 40 reads the image by imaging a film by means of transmitted or reflected light having different wavelengths.

The image processing unit 5 comprises image processing means 50 for ensuring that the correlation or ratio of the gamma value between different pieces of color information on the aforementioned multiple color images is maintained constant with respect to multiple colors of one image, wherein the aforementioned group of pixels is formed by the transmitted or reflected light having different wavelengths and is arranged in the two-dimensional plane. Color information is defined as RGB information. Further, color information is an RGB and wavelength component different from the aforementioned RGB. Furthermore, color information includes RGB and Ir information.

When the correlation and ratio of gamma values is made constant, component G is assumed as a reference, and correlation or ratio of gamma value relative to G is made constant. The correlation or ratio of gamma value is made to agree with at least invisible information.

The gamma value is measured, and the correlation or ratio of the gamma value between different pieces of color information is made constant by reading multiple films having different densities. The multiple films having different densities have multiple density areas in one frame, with the difference of adjacent densities reduced. The difference of densities is 0.5 or less in terms of density value. The correction quantity is changed for each film type.

As described above, image quality and accuracy for correction of foreign substances and damages are improved and by ensuring that the correlation or ratio of the gamma value between different pieces of color information is maintained constant.

In this present embodiment, in order to ensure that the correlation or ratio of the gamma value between different pieces of color information is maintained constant, the gamma value of the information on foreign substances and damages is corrected, for example, by LOOKUP TABLE (LUT) processing, and is made to agree with visible information, thereby improving the accuracy for correction of foreign substances and damages.

In this present embodiment, a step tablet is used to measure the gamma values of visible information and information on foreign substances and damages. Based on the result of this measurement, a Lookup Table (LUT) is created to correct gamma values. Use of the step tablet allows the chart size and the chart read time to be reduced.

Further, flare can be reduced by decreasing the difference of densities of adjacent tablets. Especially when data is extracted from the step tablet, the data is extracted from the center position, whereby the adverse effect can be reduced.

This difference of densities of adjacent tablets varies according to the coating material of the zoom lens 43 of the scanner 40, the internal structure of the zoom lens, the wavelength of the light source, and the amount of light. The adverse effect of flare is eliminated and measurement is enabled by using as the difference of densities of the step tablet half the difference of densities (appearing as pixel values) where flare raises a problem in computation of the image processing unit 5.

In such an apparatus according to the present invention, the difference of densities of 0.5 was applied since the difference of densities 1 became a problem.

The following describes an embodiment where the correlation or ratio of the gamma value between different pieces of color information is made constant.

The chart has a difference of adjacent densities of 0.5 according to the method for ensuring approximate agreement of gamma values with respect to the image comprising color components R, G, B and IR.

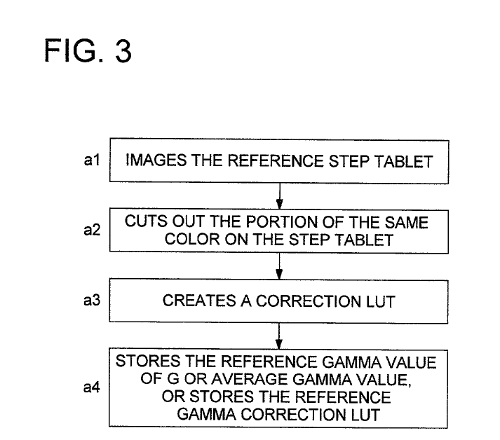

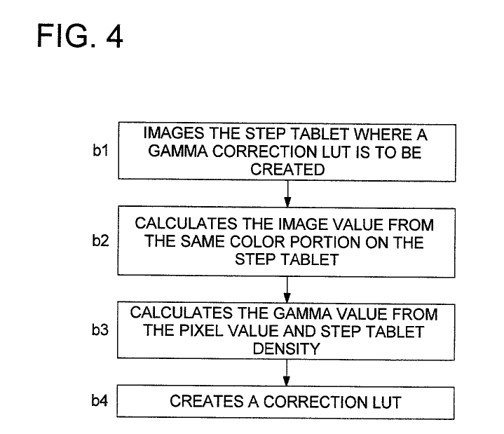

The following describes the gamma correction chart imaging procedure with reference to FIGS. 3 and 4.

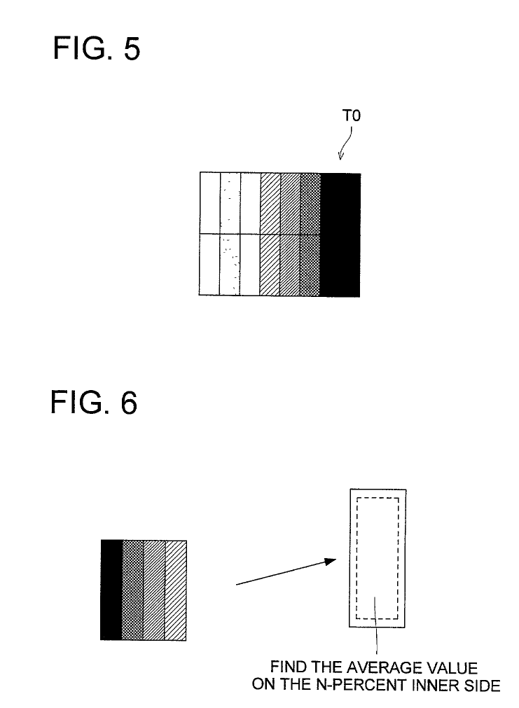

FIG. 3 is a flow chart showing the reference imaging procedure. It shows imaging of the step tablet that is sensitized on the reference negative film (for example, Konica Centuria 100), as shown in FIG. 5 (Step a1).

The portion of the same color on step tablet T0 is cut out (Step a2). As shown in FIG. 6, the average is found on the n-percent inner side, and is assumed as a pixel value in that step tablet T0. Use of n-percent inner side is intended to allow for an area detection error and microscopic flare. For example, n percent is considered as 10 percent of the tablet size.

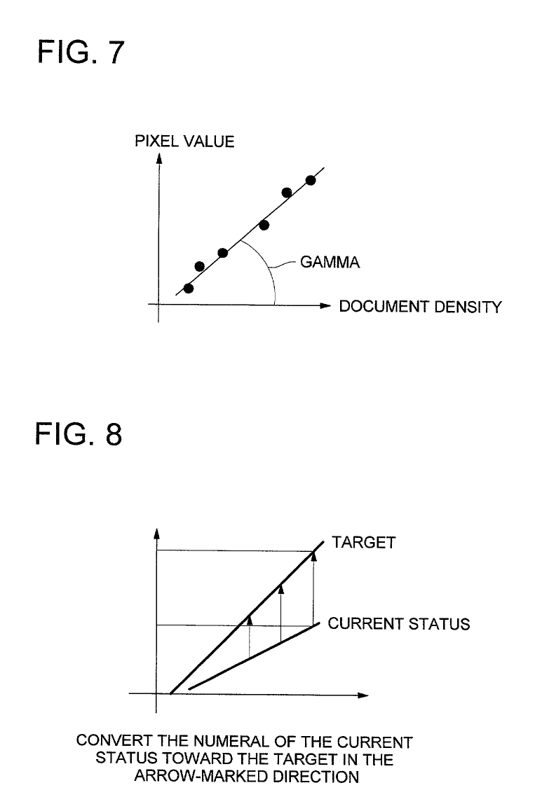

As shown in FIG. 7, plotting can be made from the density of the step tablet T0 and pixel value. This inclination is represented by gamma. When it is found out by calculation, the method of least square is applicable.

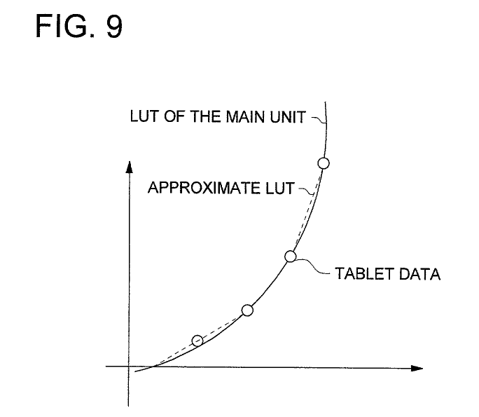

The gamma values of R, B and Ir with respect to G are compared. If they are not within a predetermined range, a difference is found to create the LOOKUP TABLE (LUT) for correction, as shown in FIG. 8 (Step a3). Since it is difficult to create a step tablet T0 for all densities, The Lookup Table (LUT) is subjected to linear interpolation, as shown in FIG. 9, whereby the insufficient area of the LOOKUP TABLE (LUT) is filled up.

The predetermined range is a gamma correction error by LOOKUP TABLE (LUT) correction, for example.

The gamma value of G as a reference or an average gamma value is stored; further, the correction LOOKUP TABLE (LUT) as a reference is also stored (Step a4).

FIG. 4 is a flowchart representing other imaging procedures.

The step tablet T0 shown in FIG. 5 exposed onto the negative film wherein one wishes to create a gamma correction Lookup Table (LUT) is imaged (Step b1). The pixel value is calculated from the portion of the same color on the step tablet T0 (Step b2). The gamma value is calculated from the pixel value and tablet density (Step b3). The gamma values of R, G, B and Ir Is compared with that of the reference G. If the result of comparison is not within a predetermined range, a gamma correction Lookup Table (LUT) is created (Step b4).

In the gamma correction method (infrared leakage), the pixel value is converted in conformity to the created Lookup Table (LUT), subsequent to the correction chart.

This produces the state of a new pixel value =Lookup Table (LUT) [imaging pixel value].

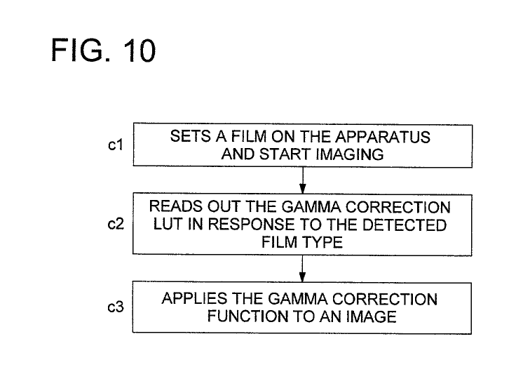

FIG. 10 shows the normal imaging procedure.

A film is loaded on the film carrier 45 of the scanner 40, and imaging operation starts (Step c1). The gamma correction Lookup Table (LUT) is read in conformity to the detected type of the film (Step c2), and the image is subjected to gamma correction (Step c3).

The following describes the second embodiment of the present invention:

In the second embodiment, an image is read from an original through the transmitted or received light having different wavelengths using the CCD 44 constituting image input means. According to this embodiment, the document is defined as a photographic film.

In the present embodiment, a group of pixels is formed by the transparent and reflected light having different wavelengths by a correction means 51 and is arranged in the two-dimensional plane, and the response characteristics of imaging is corrected in response to the magnification of imaging, with respect to multiple colors of one image. This enables a predetermined image quality to be provided despite a change in magnification of imaging. It also allows correction performances of foreign substances and damages to be improved, independently of magnification of imaging, according to the present embodiment.

This embodiment corrects the change of response characteristics, thereby stabilizing the image quality subsequent to correction of foreign substances and damages. The response characteristic of imaging at a predetermined magnification is determined as a reference, and the amount of change or rate of change in response characteristics of imaging at other magnifications.

A response characteristic of an image refers to at least one of the coordinate misregistration among various pieces of image color information, correlation of MTF, focal points of various colors, a ratio of gamma values, noise and a shading pattern.

Further, in any magnification of imaging, the aforementioned response characteristics are corrected to stay within a predetermined range with reference to the standard state. The magnification of imaging as a reference is defined as a magnification where the image quality is the optimum without any correction being made within the range of the magnification of imaging. It can also be defined as a magnification where the image quality reaches an average level without any correction being made within the range of the magnification of imaging.

A correction value table is provided for each of the magnifications of imaging which can be set. A correction table is also provided for each of magnifications of imaging at predetermined intervals. Linear interpolation is made among these magnifications of imaging at predetermined intervals.

A correction table is provided for each of the predetermined ranges of magnification of imaging, and the same correction value is used for correction at the predetermined magnification of imaging. A correction value at a reference magnification of imaging is stored, and the correction values at magnifications other than the aforementioned magnification of imaging are the differences of correction values at the aforementioned reference magnification of imaging. The changes in correction value in conformity to the magnification of imaging can be calculated from a formula.

According to the present embodiment, misregistration of the coordinate position of each component is corrected in an image consisting of a group of pixels arranged in a two-dimensional plane. A group of pixels arranged in a two-dimensional plane is divided by a predetermined value and is deformed in different amount for each of the divided areas, whereby the misregistration of coordinate position of each color component is corrected. The color components consist of B, G and R. The coordinate positions of R and B are made to agree with that of G to correct misregistration of the coordinate position of each color component.

The misregistration of coordinate position is detected by a chart containing vertical and/or horizontal bars. A fixed spacing between the vertical bars and/or horizontal bars in the chart ensures simple and easy detection of the misregistration between visible information and information on foreign substances and damages.

The chart to be used is the one without multiple color sensitive components, and is made of the material where infrared transmittance changes according to the density. It can be formed of a metal plate by etching, evaporated glass film or monochrome film.

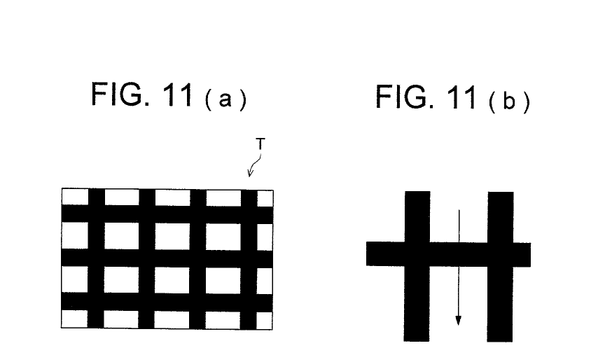

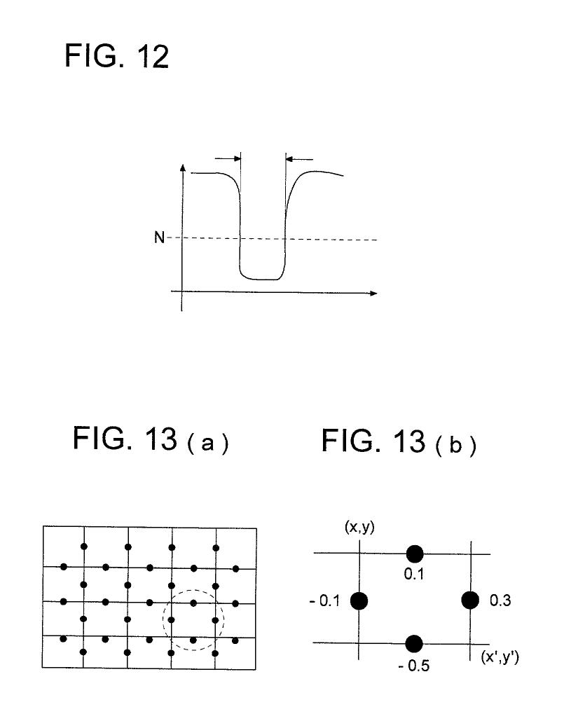

In the present embodiment, a grid chart shown in FIG. 11(a), for example, is used as Chart T. FIG. 12 shows the pixel values plotted in the arrow marked direction shown in FIG. 11(b).

The Chart T in the present embodiment contains grid-shaped vertical and horizontal bars for detecting the misregistration of coordinate positions. As shown in FIG. 11(c), if the mid-point of the position representing a density value N is assumed as a misregistration checking point on the edge, the misregistration of the X and Y coordinates of the check points among different colors denote the pixel misregistration.

The correction method will be described below: According to this method, an image taken in three colors of RGB is processed in such a way that the pixel misregistration of G and R are corrected with reference to the R.

The misregistration from the Chart T shown in FIG. 11(a) was measured. The checkpoints used in this case are represented by the black dots shown in FIG. 13(a). FIG. 13(b) pays attention to a particular point. The coordinates in the upper left-hand corner of a square area surrounded by the checkpoints are assumed as (x, y), and those in the lower left-hand corner are (x′, y′).

The misregistration of red from green at each checkpoint is given below the black dots in FIG. 13(b) For example, “0.3” represents the misregistration of red from the green when the edge is checked toward the right horizontally in the x direction. In this case, the change from x to x′ is regarded as linear change of the misregistration from −0.1 to 0.3. Similarly, the change from y to y′ is regarded as a linear change of the misregistration from 0.1 to −0.5. Based on this, misregistration is corrected according to deformation processing by computation of interpolation such as neighborhood interpolation or linear interpolation to ensure that the area surrounded by a square will agree with the G coordinate.

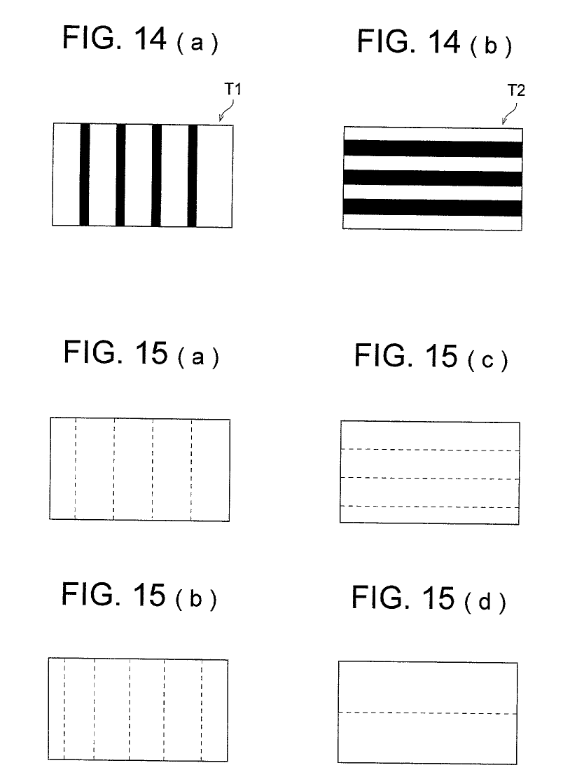

Further, The vertical bar chart T1 shown in FIG. 14(a) and horizontal bar chart T2 shown in FIG. 14(b) can be used in the present embodiment.

The average misregistration of pixels in each line is calculated from the aforementioned charts T1 and T2, and the image is divided according to the charts, as shown in FIGS. 15(a), 15(b), 15(c) and 15(d). FIG. 15(a) shows an example of division based on the black bar reference of the image according to the vertical bar chart T1. FIG. 15(b) shows an example of division based on the white bar reference of the image according to the vertical bar chart T1. FIG. 15(c) is an example of division based on the black bar reference of the image according to the horizontal bar chart T2. FIG. 15(d) is an example of division where the number of divisions is smaller than that on the upper line of the chart, based on the black bar reference of the image according to the horizontal bar chart T2.

As described above, deformation operation is performed in response to the average misregistration of pixels for each area separated by a dot line in FIGS. 15(a), 15(b), 15(c) and 15(d). In the case of the vertical chart T1, deformation is exhibited only in the horizontal direction. In the case of the vertical chart T2, deformation is exhibited only in the vertical direction. There is no need for a complete agreement between the number of the bars on the chart and the area where deformation operation is performed. Division of the area where deformation operation is performed can be made below the bar of the chart. As shown in FIGS. 15(a), 15(b), 15(c) and 15(d), when division is made, the white line can be used as a reference, instead of the black line on the chart.

In the present embodiment, misregistration is calculated based on the characteristics formula of the chromatic aberration of magnification for horizontal scanning of reading by the scanner 40. Since the misregistration of pixels is not restricted only to the chromatic aberration of magnification, the misregistration among girds arranged at a predetermined spacing is subjected to linear interpolation, whereby a misregistration correction table is created. Switching of the misregistration function is performed on a regular basis when a predetermined spacing is provided, and this ensures a simple configuration.

Color misregistration occurs when the chart is imaged using a color negative film. Namely, the color negative film is a collection of multiple pigments, and it is impossible that they are uniformly arranged without displacement among themselves. For example, even if a black/white streak patterned chart is imaged, there is no perfect agreement between the edge of the pigment corresponding to the B on the film and that corresponding to the G. In the meantime, the misregistration of the pixels to be corrected is smaller than that of the negative film, so a monochrome film or the like is suitable.

The color components in the present embodiment are B, G and R, and the R and B are made to agree with G. In other words, pixel misregistration of R, G, B and Ir is corrected with reference to G. A chart is used to detect the coordinate displacement, and the amount of misregistration is measured for each type of the film. This is formulated into a table, and correction is performed according to the detected type film.

This correction means 51 corrects the difference of sharpness among different pieces of color information. Color information is RGB in terms of visible light. Color information consists of visible information and information on foreign substances and damages. Information on foreign substances and damages is the information imaged by infrared rays. Further, in the correction of the difference in sharpness among different pieces of color information, the extent of correcting the sharpness of the R and G is determined with reference to G. Further, correction is made in such a way that the relationship of sharpness among different pieces of color information will be constant.

Further, correction is made in such a way that the relationship of sharpness among different pieces of color information will be constant in response to the type of film. In the step of correcting the sharpness, an upper limit is established so that the amount of correction does not exceed a predetermined percentage.

In the present embodiment, the difference of sharpness between visible image and foreign substance/damage can be reduced by correcting the difference in sharpness through image-processing. Color blur on the image contour is eliminated and image quality is improved by correcting the difference of sharpness. At the same time, when the foreign substances and damages are corrected using information on foreign substances and damages, it is possible to improve the accuracy of improving the foreign substances and damages.

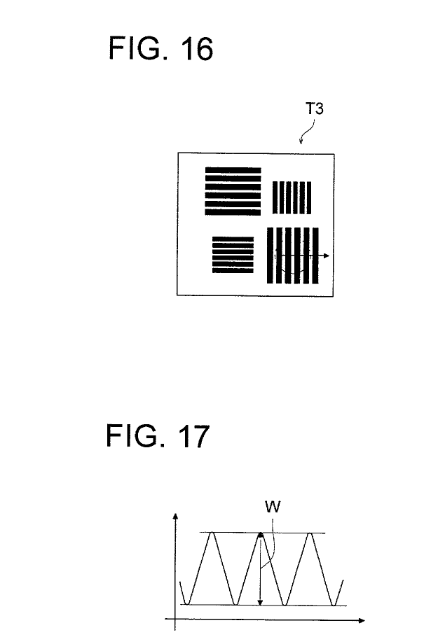

In the present embodiment, sharpness can be improved by enhancing the sharpness to correct the difference among different pieces of color information. For example, a third- or fifth-order film is used. The chart shown in FIG. 16 is imaged and the amplitude of the chart is measured as a degree of sharpness, as shown in FIG. 17.

In other words, Chart T3 has multiple frequency bars shown in both the horizontal and vertical directions on one side, as shown in FIG. 13. The portions encircled in FIG. 13 are scanned in the arrow-marked direction and the amplitude of the waveform is assumed as a degree of sharpness at the scanned frequency. Frequency corresponds to the number of pair lines per 1 mm. The smaller the number, the lower the frequency, while the higher the number, the higher the frequency. If chart T3 is created in such a way that all the values of white and black of the streak pattern printed on the film are the same, changes of frequency can be expressed by the amplitude of other frequencies in terms of ratio, based on the amplitude at a low frequency because low frequency is hardly deteriorated. When the black and white on the chart T3 differs according to frequency, namely, the ratio of amplitude with respect to low frequency is stored in the memory because of deterioration of sharpness at the time of imaging the chart, and the ratio of amplitude between the low frequency of chart T3 and other frequency is multiplied by the ratio of amplitude on the chart T3, whereby a desired sharpness is obtained.

Imaging sharpness=amplitude of measured frequency/amplitude of minimum frequency x amplitude of minimum frequency on chart/amplitude of measured frequency on chart FIG. 17 shows the data obtained by cutting across the streak on chart T3. The amplitude value is assumed as a degree of sharpness at that frequency.

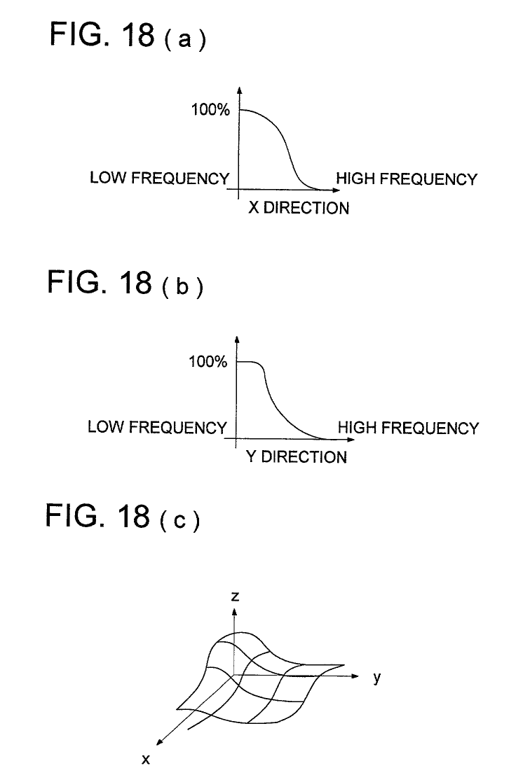

In the present embodiment, filter coefficient is calculated from the deteriorated state of the amplitude. In other words, if changes in sharpness in the x and y directions are known, a frequency deterioration curve of x and y can be derived as shown in FIGS. 18(a), 18(b) and 18(c). From this, as shown in FIG. 18(c), the n-th order filter coefficient is calculated and is assumed as a filter coefficient of this color in the reference state. This filter coefficient for sharpness correction is applied to the color in question to calculate the ratio of amplitude.

In the present embodiment, when the degree of sharpness is measured for each type of film, it is necessary to ensure that the amount of correction due to filter calculation is kept below a certain level (for example, 40 percent. In the case of sharpness enhancement, enhancement is restricted to less than 140 percent of the original level).

According to this method, the chart for all film types including the state of reference is imaged, and the reference state is determined thereafter. In addition to this step, coefficients of sharpness enhancing filters for all film types are calculated and stored on the table. The step of sharpness enhancement has a problem of noise being increased with the amount of correction. To prevent noise from affecting the image quality, an upper limit is provided. This upper limit varies according to the method of enhancing the sharpness.

The following describes the embodiment of correcting the differences of sharpness among different pieces of color information. The sharpness of the R, B and Ir is corrected with reference to the G. FIG. 11(a) shows the sharpness measurement chart. State of reference is the state for imaging the chart created by the reference film (e.g. Centuria 100 of Konica). This state refers to the shading pattern, amount of dimmed light, etc.

This correction means 51 keeps the difference of gamma levels among different pieces of color information at a certain level. Color information refers to the RGB. The color information refers to components having wavelengths different from those of the aforementioned RGB. It also includes the RGB and Ir.

When the difference of gamma level is kept at a certain level, component G is used as a reference, whereby the difference of gamma is kept at a certain level with reference to G. Agreement of at least the visible information is essential for the difference of gamma.

Gamma is measured by reading multiple films having different densities, and the difference of gamma levels among pieces of color information is kept at a certain level. The aforementioned multiple films having different densities have multiple density areas in one frame to reduce the difference of adjacent densities. For the difference of densities, the density value is 0.5 or less. The amount of gamma correction is changed for each type of film.

As described above, the difference of gamma between different pieces of color information is made constant, thereby improving image quality and accuracy of correcting the error resulting from foreign substances and damages.

In the present embodiment, in order to keep the difference of gamma among different pieces of color information at a certain level, gamma of the information on foreign substances and damages is corrected, for example, by LUT processing, and agreement of visible information is achieved. In this manner, the accuracy of correcting the foreign substances and damages is improved.

In the present embodiment, the step tablet is used to measure the gamma level of visible information and information on foreign substances and damages. A Lookup Table (LUT) is created based on the result of this measurement to correct gamma. Use of the step tablet allows the chart size and the chart readout time to be reduced.

Flare can be reduced by decreasing the difference in the density of a tablet, using a step tablet. Especially when the data is extracted from the step, the adverse effect of flare can be reduced by extracting it from the central position.

The difference of adjacent densities varies according to the coating material of the zoom lens 43 of the scanner 40. Half the difference of density where flare raises a problem of computation by the image processing unit 5 (appearing a pixel value) is used as a difference in density of the step tablet, thereby ensuring measurement without adverse effect of flare.

In the apparatus according to this invention, a computational problem of the difference in density 1 occurred. So density difference of 0.5 was applied.

The aforementioned correction means 51 performs correction in such a way that the image will be kept within a predetermined range in any magnification of imaging, with reference to the standard state. The magnification of imaging as a reference is defined as a magnification where the image quality is the optimum without any correction being made within the range of the magnification of imaging. It can also be defined as a magnification where the image quality reaches an average level without any correction being made within the range of the magnification of imaging.

A correction value table is provided for each of the magnifications of imaging which can be set. This table is used to make correction. A correction table is also provided for each of magnifications of imaging at predetermined intervals. Linear interpolation is made among these magnifications of imaging at predetermined intervals. A correction table is also provided for each of the predetermined ranges of magnification of imaging, and the same correction value is used for correction at the predetermined magnification of imaging.

A correction value at a reference magnification of imaging is stored, and the correction values at magnifications other than the aforementioned magnification of imaging are the differences of correction values at the aforementioned reference magnification of imaging. The changes in correction value in conformity to the magnification of imaging can be calculated from a formula.

The following describes the normal operation of the aforementioned scanner system: The controller 3 calculates zoom magnification in conformity to the type of film (APS, 135, negative/positive films, etc.) and the preset size of imaging. Information on magnification is sent to the zoom lens 43 to drive a zoom and to perform automatic focusing operation (AF).

Then the film is loaded in position, and the film base and type are read by the film scanner 45. The result is sent to the controller 3, which sends the information on the amount of light in conformity to the base density and film type so that the light source unit 41 controls light.

The controller 3 sends the information on selection filter number, and the filter unit 42 sets the selected filter.

The controller 3 sends to the image processing unit 5 the parameters (amounts of pixel misregistration correction, gamma correction and sharpness correction) required for image processing in response to the film.

Shading correction is performed or reads the shading parameter in conformity to the type of film, and the film is imaged.

The image processing unit 5 processes the image information sent from the CCD 44, and the image information is output from the image output unit 6.

The following describes the correction registration operation of the aforementioned scanner system:

The controller 3 calculates zoom magnification in conformity to the type of film (APS, 135, negative/positive films, etc.) and the preset size of imaging. Information on magnification is sent to the zoom lens 43 to drive a zoom and to perform automatic focusing operation (AF).

Then the reference magnification is set and a chart film is loaded in position. The film base and type are read and the result is sent to the controller 3.

The controller 3 sends the information on the amount of light in conformity to base density and film type, and the light source unit 41 controls light.

The chart and step tablet are imaged and the chart is analyzed to calculate the filter coefficient, the amount of infrared ray, offset value and gamma correction value. Similarly to the step of recording, filter number, the amount of infrared ray, offset value and gamma correction value are sent.

The filter unit 42 sets the filter and the light source unit 41 controls the amount of infrared ray. The image processing unit 5 performs offset adjustment thereafter.

The misregistration/sharpness measuring chart is imaged, and the amounts of misregistration and sharpness correction are calculated.

The filter number, the amount of infrared ray and offset value are reset to the initial values.

The magnification is changed and the aforementioned steps are repeated. When the correction value is recorded, the difference from the aforementioned reference value is recorded.

After the aforementioned steps have been performed at the magnification calculated from the table, the document film is switched.

The following describes a third embodiment according to the present invention. First, the correction of the aforementioned scanner system is explained. In the third embodiment, a scanner 40 images the film using the transmitted light and reflected light having different waveforms and reads the image. The image processing unit 5 comprises correction means for correcting the misregistration of coordinate position for each color component with respect to multiple colors of one image; wherein a group of pixels is formed by the transmitted or reflected light of different wavelengths input in the step of image reading and is arranged in a two-dimensional plane.

A group of pixels arranged in a two-dimensional plane is divided by a predetermined value and is deformed in different amount for each of the divided areas, whereby the misregistration of coordinate position of each color component is corrected. These color components consist of B, G and R. The coordinate positions of R and B are made to agree with that of G to correct misregistration of the coordinate position of each color component.

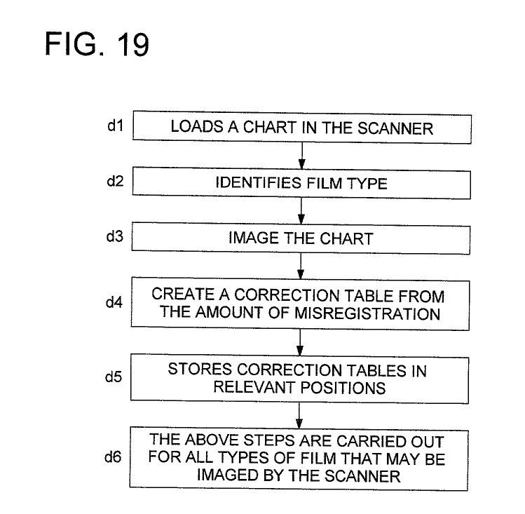

The pixel misregistration setting procedure in the overall sequence of this scanner system 1 will be explained with reference to FIG. 19.

A chart is placed into a film carrier 45 of the a carrier 40 (Step a1), and the film type is identified by the controller 3 based on the information on film type in conformity to the chart from this film carrier 45 (Step d2).

This chart is imaged (Step d3), and a correction table is created according to the amount of misregistration (Step d4). These steps are performed for all types of film that can be imaged by the scanner 40.

The correction table created according to the aforementioned steps is stored in the storage unit installed on the controller 3 that controls a scan system 1 or scanner 40. They include a rewritable ROM, hard disk and the like. This correction table is created or updated at the time of shipment, installation, periodic maintenance or the like.

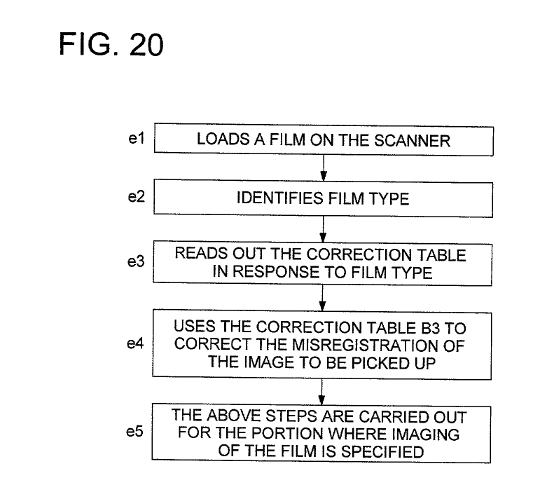

The following describes the normal imaging procedure of this scanner system with reference to maintenance FIG. 20:

A film F is loaded into the film carrier 45 of the scanner 40 (Step e1), and the film type is identified by the controller 3 based on the information on film type from this film carrier 45 (Step e2).

The controller 3 reads a correction table in conformity to the type of film (Step e3). If there is no relevant type of film, a correction table for the type of the film having a similar base density or specific type of film having the same sensitivity is used. If the information on film type cannot be obtained, the correction table for the standard film is used.

The correction table is used to correct the misregistration of the image picked up. This step of misregistration correction is performed for a designated portion (Step e5).

The aforementioned specific type of film refers to Konica Centuria, for example, and the standard film is Konica Centuria 400, for example. A film having a specific sensitivity made by a specific manufacturer is specified. The user of the scanner can change this specification.

Such a scanner system 1 photoelectrically reads the image recorded on the film by the scanner 40. The information on foreign substances and damages is imaged in the range of wavelength different from that of the BGR. After the coordinate of the information on foreign substances and damages has been made to agree with that of the BGR image based on the information on foreign substances and damages, the foreign substances and damages of the BGR image information are corrected. The BGR image information is visible information formed of color information perceptible to humans. The information on foreign substances and damages is the information on foreign substances, damages, dust or dirt that was not present in the beginning. This information is picked up by infrared rays.

When foreign substances and damages of the BGR image information is corrected, the coordinate of the information on foreign substances and damages is made to agree with that of the BGR. Deterioration of sharpness and color blurring can be avoided by correcting the misregistration of visible information.

In the present embodiment, correction of foreign substances and damages can be performed after correction of the coordinate. Alternatively, it can be performed by making reference to the amount of coordinate correlation. Alternatively, the amount of correlation can be switched for each magnification of imaging, based on the individual amount of pre-detected correction, newly acquired amount of correction or computation for correction.

In the present embodiment, deterioration of image quality resulting from correction of foreign substances and damages can be avoided by correction of misregistration of the visible information through correction in conformity to visible standards because of;

misregistration of coordinate position between visible light and information on foreign substances and damages;

difference between sharpness between the visible and infrared rays;

changes in characteristic relationship due to fluctuations of equipment status; and,

in an apparatus loaded with a zoom lens, misregistration between the visible information formed of color information perceptible to humans as a photograph and image due to changes of individual characteristic relationship resulting from change of magnification and the information on foreign substances and damages not present on the film in the beginning.

It is also possible to correct chromatic aberration in magnification of imaging, CCD setup deviation, misregistration due to light transmission and refractive index in conformity to film type, instrumental error, film transport irregularity and the like.

As described above, to the present invention provides the following effects:

(1) Image quality is improved and accuracy of correcting foreign substances and damages is upgraded by the configuration wherein a group of pixels is formed by the transmitted or reflected light and is arranged in the two-dimensional plane, and the correlation or ratio of the gamma value between different pieces of color information on multiple color images is maintained constant with respect to these multiple colors of one image.

(2) Stable image quality is ensured despite changes in the imaging magnification and the performance of correcting foreign substances and damages is improved, independently of imaging magnification, by the configuration wherein the an image is read from a document by means of the transmitted or reflected light of different wavelengths, a group of pixels is formed by the transmitted or reflected light and is arranged in the two-dimensional plane, and the response characteristics for imaging are corrected in response to magnification of imaging, with respect to multiple colors of one image.

(3) Misregistration of visible information is corrected by the configuration wherein a group of pixels is formed by the transmitted or reflected light of different wavelengths for image reading and is arranged in the two-dimensional plane; and the misregistration of coordinate position for each color component is corrected with respect to multiple colors of one image. Further, the accuracy of correcting foreign substances and damages is improved by eliminating differences between information on foreign substances and damages and visible information.

Disclosed embodiment can be varied by a skilled person without departing from the spirit and scope of the invention.

What is claimed is:

1. A method of processing an image recorded on a film, comprising the steps of:
irradiating a plurality of lights, whose wavelengths are different relative to each other, onto said film;
reading said image by detecting said plurality of lights transmitted through said film or reflected from said film placed, so as to generate a plurality of color image data sets corresponding to a plurality of color images included in said image; and
processing said plurality of color image data sets, so as to keep each of relative relationships or each of ratios, between gamma values of said plurality of color images, substantially constant.

2. The method of claim 1,
wherein said plurality of color images include a Red image, a Green image and a Blue image.

3. The method of claim 1,
wherein said plurality of color images include a Red image, a Green image, a Blue image and a specific image having a wavelength other than those of said Red image, said Green image and said Blue image.

4. The method of claim 3,
wherein said specific image is an infrared image.

5. The method of claim 3,
wherein said Green image is selected as a reference image for processing said plurality of color image data sets, and each of said relative relationships or each of said ratios, between a gamma value of said Green image and each of gamma values of said Red image, said Blue image and said specific image, is kept substantially constant.

6. The method of claim 5,
wherein each of said relative relationships or each of said ratios, between a gamma value of said Green image and each of gamma values of said Red image and said Blue image, is kept substantially constant.

7. The method of claim 1,
wherein each of said gamma values is measured by reading a plurality of solid image areas, whose densities are different relative to each other, and each of which is recorded on each of a plurality of films.

8. The method of claim 1,
wherein each of said gamma values is measured by reading a plurality of solid image areas, whose densities are different relative to each other, and which are recorded within a single frame of a film; and
wherein said plurality of solid image areas are arrayed in order of their density strengths.

9. The method of claim 8,
wherein each density difference value between two adjacent solid image areas of said plurality of solid image areas is not greater than 0.5.

10. The method of claim 1,
wherein each of said gamma values of said plurality of color images is compensated for, so as to keep each of said relative relationships or each of said ratios constant; and
wherein each of compensated gamma values of said plurality of color images is changed corresponding to a kind of said film.

11. An apparatus for processing an image recorded on a film, comprising:
a light source to emit a plurality of lights, whose wavelengths are different relative to each other, and which are irradiated onto said film;
an image-reading section to read said image by detecting said plurality of lights transmitted through said film or reflected from said film placed, so as to generate a plurality of color image data sets corresponding to a plurality of color images included in said image; and
an image-processing section to process said plurality of color image data sets, so as to keep each of relationships or each of ratios, between gamma values of said plurality of color images, substantially constant.

12. The apparatus of claim 11,
wherein said plurality of color images include a Red image, a Green image and a Blue image.

13. The apparatus of claim 11,
wherein said plurality of color images include a Red image, a Green image, a Blue image and a specific image having a wavelength other than those of said Red image, said Green image and said Blue image.

14. The apparatus of claim 13,
wherein said specific image is an infrared image.

15. The apparatus of claim 13,
wherein said Green image is selected as a reference image for processing said plurality of color image data sets, and each of said relative relationships or each of said ratios, between a gamma value of said Green image and each of gamma values of said Red image, said Blue image and said specific image, is kept substantially constant.

16. The apparatus of claim 15,
wherein each of said relative relationships or each of said ratios, between a gamma value of said Green image and each of gamma values of said Red image and said Blue image, is kept substantially constant.

17. The apparatus of claim 11,
wherein each of said gamma values is measured by reading a plurality of solid image areas, whose densities are different relative to each other, and each of which is recorded on each of a plurality of films.

18. The apparatus of claim 11,
wherein each of said gamma values is measured by reading a plurality of solid image areas, whose densities are different relative to each other, and which are recorded within a single frame of a film; and
wherein said plurality of solid image areas are arrayed in order of their density strengths.

19. The apparatus of claim 18,
wherein each density difference value between two adjacent solid image areas of said plurality of solid image areas is not greater than 0.5.

20. The apparatus of claim 11,
wherein each of said gamma values of said plurality of color images is compensated for, so as to keep each of said relative relationships or each of said ratios constant; and
wherein each of compensated gamma values of said plurality of color images is changed corresponding to a kind of said film.

21. A method of processing an image recorded on a document, comprising the steps of:
irradiating a plurality of lights, whose wavelengths are different relative to each other, onto said document;
reading said image by detecting said plurality of lights transmitted through said document or reflected from said document placed, so as to generate a plurality of color image data sets corresponding to a plurality of color images included in said image; and
processing said plurality of color image data sets, so as to compensate for photographing-response characteristics in respect to each of said plurality of color images, corresponding to variations of an image-magnification factor for every photographing-operation.

22. The method of claim 21,
wherein an image of a foreign substance or a scar on said document is substantially eliminated by compensating for said photographing-response characteristics.

23. The method of claim 21,
wherein either an amount-of-change or a rate-of-change, between first photographing-response characteristics at a certain image-magnification factor, serving as a reference image-magnification factor, and second photographing-response characteristics at another image-magnification factor, is compensated for.

24. The method of claim 21,
wherein said photographing-response characteristics includes at least one of factors, which are misregistration of said plurality of color images, correlation of MTF characteristics, focusing properties of said plurality of color images, ratios between gamma values of said plurality of color images, noises and shading patterns.

25. The method of claim 21,
wherein said photographing-response characteristics are compensated for within a predetermined range, irrespective of any variations of said image-magnification factor.

26. The method of claim 23,
wherein a best image-quality is obtained at said reference image-magnification factor without compensating for said photographing-response characteristics in a range of said variations of said image-magnification factor.

27. The method of claim 23,
wherein an average image-quality is obtained at said reference image-magnification factor without compensating for said photographing-response characteristics in a range of said variations of said image-magnification factor.

28. The method of claim 21,
wherein a table of compensation values is provided for every image-magnification factor to be set.

29. The method of claim 21, wherein a table of compensation values is provided for each of image-magnification factors divided into predetermined intervals, and gaps between said image-magnification factors are linearly interpolated.

30. The method of claim 21,
wherein a table of compensation values is provided for each of predetermined ranges of said image-magnification factor, and said photographing-response characteristics are compensated for by employing a same compensation value within each of said predetermined ranges of said image-magnification factor.

31. The method of claim 23,
wherein first compensation values at said reference image-magnification factor are stored, and second compensation values at another image-magnification factor other than said reference image-magnification factor are differential components of said first compensation values.

32. The method of claim 31,
wherein variations of compensation values by said image-magnification factor are calculated by employing a formula.

33. The method of claim 21,
wherein said document is a photographic-film.

34. An apparatus for processing an image recorded on a document, comprising:
a light source to emit a plurality of lights, whose wavelengths are different relative to each other, and which are irradiated onto said document;
an image-reading section to read said image by detecting said plurality of lights transmitted through said document or reflected from said document placed, so as to generate a plurality of color image data sets corresponding to a plurality of color images included in said image; and
an image-processing section to process said plurality of color image data sets, so as to compensate for photographing-response characteristics in respect to each of said plurality of color images, corresponding to variations of an image-magnification factor for every photographing-operation.

35. The apparatus of claim 34,
wherein an image of a foreign substance or a scar on said document is substantially eliminated by compensating for said photographing-response characteristics.

36. The apparatus of claim 34,
wherein either an amount-of-change or a rate-of-change, between first photographing-response characteristics at a certain image-magnification factor, serving as a reference image-magnification factor, and second photographing-response characteristics at another image-magnification factor, is compensated for.

37. The apparatus of claim 34,
wherein said photographing-response characteristics includes at least one of factors, which are misregistration of said plurality of color images, correlation of MTF characteristics, focusing properties of said plurality of color images, ratios between gamma values of said plurality of color images, noises and shading patterns.

38. The apparatus of claim 34,
wherein said photographing-response characteristics are compensated for within a predetermined range, irrespective of any variations of said image-magnification factor.

39. The apparatus of claim 36,
wherein a best image-quality is obtained at said reference image-magnification factor without compensating for said photographing-response characteristics in a range of said variations of said image-magnification factor.

40. The apparatus of claim 36,
wherein an average image-quality is obtained at said reference image-magnification factor without compensating for said photographing-response characteristics in a range of said variations of said image-magnification factor.

41. The apparatus of claim 34,
wherein a table of compensation values is provided for every image-magnification factor to be set.

42. The apparatus of claim 34,
wherein a table of compensation values is provided for each of image-magnification factors divided into predetermined intervals, and gaps between said image-magnification factors are linearly interpolated.

43. The apparatus of claim 34,
wherein a table of compensation values is provided for each of predetermined ranges of said image-magnification factor, and said photographing-response characteristics are compensated for by employing a same compensation value within each of said predetermined ranges of said image-magnification factor.

44. The apparatus of claim 36,
wherein first compensation values at said reference image-magnification factor are stored, and second compensation values at another image-magnification factor other than said reference image-magnification factor are differential components of said first compensation values.

45. The apparatus of claim 44,
wherein variations of compensation values by said image-magnification factor are calculated by employing a formula.

46. The apparatus of claim 34,
wherein said document is a photographic-film.

47. A method of processing an image recorded on a film, comprising the steps of:
irradiating a plurality of lights, whose wavelengths are different relative to each other, onto said film;
reading said image by detecting said plurality of lights transmitted through said film or reflected from said film placed, so as to generate a plurality of color image data sets corresponding to a plurality of color images included in said image; and
processing said plurality of color image data sets, so as to compensate for misregistrations between positional coordinates of said plurality of color images.

48. The method of claim 47,
wherein each of said plurality of color images is constituted by pixels, which are arrayed in two-dimensional directions of rows and lines, and are divided into a predetermined number of unit pixel areas; and
wherein said misregistrations between said positional coordinates of said plurality of color images are compensated for by deforming pixels included in each of said unit pixel areas with each of deforming amounts being different relative to each other.

49. The method of claim 47,
wherein said plurality of color images include a Red image, a Green image and a Blue image; and
wherein said misregistrations between said positional coordinates of said plurality of color images are compensated for by matching positional coordinates of said Red image and said Blue image with that of said Green image.

50. The method of claim 49,
wherein a light, having a wavelength other than those of said Red image, said Green image and said Blue image is irradiated onto said film to capture a specific image of a foreign substance or a scar on said film; and
wherein, after matching a positional coordinate of said specific image with those of said Red image, said Green image and said Blue image, foreign substance or scar images, recorded on said Red image, said Green image and said Blue image, are compensated for, based on information in regard to said specific image of said foreign substance or said scar.

51. The method of claim 50,
wherein said positional coordinate of said specific image is matched with a positional coordinate of said Green image.

52. The method of claim 50,
wherein an Infrared light is irradiated onto said film to capture said specific image of said foreign substance or said scar on said film; and

53. The method of claim 47,
wherein a chart, on which either vertical lines or horizontal lines, or both of them are depicted, is employed for detecting misregistrations between said positional coordinates of said plurality of color images.

54. The method of claim 53,
wherein either said vertical lines or said horizontal lines, or both of them are arrayed in (a) vertical and/or horizontal direction(s) with predetermined intervals between them in said chart.

55. The method of claim 54,
wherein said chart has only a single color-sensitive component.

56. The method of claim 53,
wherein said chart is made of such a material that an Infrared-transmittance varies with changes in density.

57. The method of claim 53,
wherein said chart is made of one of materials including a metal-plate made by etching, a vaporized glass filter and a monochrome film.

58. The method of claim 47,
wherein compensation amounts for compensating said positional coordinates of said plurality of color images are changed, corresponding to every kind of said film.

59. The method of claim 58,
wherein foreign substance or scar images are compensated for, after compensating said positional coordinates of said plurality of color images.

60. The method of claim 58,
wherein foreign substance or scar images are compensated for, referring to said compensation amounts for compensating said positional coordinates of said plurality of color images.

61. The method of claim 58,
wherein, based on individual compensation amounts detected in advance, compensation amounts newly acquired or compensation calculations, said compensation amounts are changed, corresponding to everyone of image-magnification factors.

62. An apparatus for processing an image recorded on a film, comprising:
a light source to emit a plurality of lights, whose wavelengths are different relative to each other, and which are irradiated onto said film;
an image-reading section to read said image by detecting said plurality of lights transmitted through said film or reflected from said film placed, so as to generate a plurality of color image data sets corresponding to a plurality of color images included in said image; and
an image-processing section to process said plurality of color image data sets, so as to compensate for misregistrations between positional coordinates of said plurality of color images.

63. The apparatus of claim 62,
wherein each of said plurality of color images is constituted by pixels, which are arrayed in two-dimensional directions of rows and lines, and are divided into a predetermined number of unit pixel areas; and
wherein said misregistrations between said positional coordinates of said plurality of color images are compensated for by deforming pixels included in each of said unit pixel areas with each of deforming amounts being different relative to each other.

64. The apparatus of claim 62,
wherein said plurality of color images include a Red image, a Green image and a Blue image; and
wherein said misregistrations between said positional coordinates of said plurality of color images are compensated for by matching positional coordinates of said Red image and said Blue image with that of said Green image.

65. The apparatus of claim 64,
wherein a light, having a wavelength other than t-hose of said Red image, said Green image and said Blue image is irradiated onto said film to capture a specific image of a foreign substance or a scar on said film; and
wherein, after matching a positional coordinate of said specific image with those of said Red image, said Green image and said Blue image, foreign substance or scar images, recorded on said Red image, said Green image and said Blue image, are compensated for, based on information in regard to said specific image of said foreign substance or said scar.

66. The apparatus of claim 65,
wherein said positional coordinate of said specific image is matched with a positional coordinate of said Green image.

67. The apparatus of claim 65,
wherein an Infrared light is irradiated onto said film to capture said specific image of said foreign substance or said scar on said film; and

68. The apparatus of claim 62,
wherein a chart, on which either vertical lines or horizontal lines, or both of them are depicted, is employed for detecting misregistrations between said positional coordinates of said plurality of color images.

69. The apparatus of claim 68,
wherein either said vertical lines or said horizontal lines, or both of them are arrayed in (a) vertical and/or horizontal direction(s) with predetermined intervals between them in said chart.

70. The apparatus of claim 69,
wherein said chart has only a single color-sensitive component.

71. The apparatus of claim 68,
wherein said chart is made of such a material that an Infrared-transmittance varies with changes in density.

72. The apparatus of claim 68,
wherein said chart is made of one of materials including a metal-plate made by etching, a vaporized glass filter and a monochrome film.

73. The apparatus of claim 62,
wherein compensation amounts for compensating said positional coordinates of said plurality of color images are changed, corresponding to every kind of said film.

74. The apparatus of claim 73,
wherein foreign substance or scar images are compensated for, after compensating said positional coordinates of said plurality of color images.

75. The apparatus of claim 73,
wherein foreign substance or scar images are compensated for, referring to said compensation amounts for compensating said positional coordinates of said plurality of color images.

76. The apparatus of claim 73,
wherein, based on individual compensation amounts detected in advance, compensation amounts newly acquired or compensation calculations, said compensation amounts are changed, corresponding to everyone of image-magnification factors.
